(19) United States
(12) Patent Application Publication
(10) Pub. No.: US 2025/0046692 A1
(43) Pub. Date: Feb. 6, 2025

(54) WIRING SUBSTRATE AND SEMICONDUCTOR PACKAGE INCLUDING THE SAME

(71) Applicant: SAMSUNG ELECTRONICS CO., LTD., SUWON-SI (KR)

(72) Inventor: YOUNGBAE KIM, Suwon-si (KR)

(21) Appl. No.: 18/582,798

(22) Filed: Feb. 21, 2024

(30) Foreign Application Priority Data
Aug. 2, 2023 (KR) 10-2023-0101111

(51) Int. Cl. H01L 23/498; H01L 23/00; H01L 23/538; H01L 25/065

(52) U.S. Cl. CPC H01L 23/49822; H01L 23/49816; H01L 23/5381; H01L 24/08; H01L 24/16; H01L 25/0652; H01L 2224/08146; H01L 2224/08155; H01L 2224/16146; H01L 2224/16157; H01L 2924/01013; H01L 2924/01029; H01L 2924/01074; H01L 2924/1434; H01L 2924/15311; H01L 2924/182

(57) ABSTRACT

A wiring substrate includes a first re-distribution layer, a second re-distribution layer on the first re-distribution layer, and a core portion between the first re-distribution layer and the second re-distribution layer, wherein the core portion includes a bottom surface disposed on a top surface of the first re-distribution layer, and a first intermediate surface disposed on the top surface of the first re-distribution layer, wherein a distance between the top surface of the first re-distribution layer and the core portion along the first intermediate surface, which is measured in a direction perpendicular to the top surface of the first re-distribution layer, increases as a distance from the bottom surface increases.

### CROSS-REFERENCE TO RELATED APPLICATION

This patent application claims priority under 35 U.S.C. § 119 to Korean Patent Application No. 10-2023-0101111, filed on Aug. 2, 2023, in the Korean Intellectual Property Office, the entire contents of which are hereby incorporated by reference.

### TECHNICAL FIELD

The present disclosure relates to a wiring substrate and a semiconductor package including the same.

### DISCUSSION OF RELATED ART

Due to increasing demand for a high density and high performance electronic device, highly reliable materials are increasingly needed for a circuit board, which may be a component of the electronic device. The circuit board may include interconnection layers and an insulating layer, which may be alternately stacked and used for interconnection between circuits and as an interlayer dielectric element, respectively. In general, the interconnection layer may be formed of a metallic material (e.g., copper), and the insulating layer may be formed of polymer resins (e.g., resin or epoxy).

To reduce a thickness of the circuit board, a thickness of the insulating layer may be reduced, but if the insulating layer is too thin, it may be difficult to control a warpage property. For example, since the insulating layer has a low thermal expansion coefficient, a high glass transition temperature (High Tg), and a high modulus, compared with the interconnection layer of the metallic material, there may be difficulty in controlling electrical, thermal, and mechanical properties of the circuit board.

### SUMMARY

An embodiment of the inventive concept provides a wiring substrate with improved mechanical durability, a semiconductor package including the same, and a method of fabricating the wiring substrate.

According to an embodiment of the inventive concept, a semiconductor package may include a wiring substrate, a first chip on the wiring substrate, and a second chip on the wiring substrate and horizontally spaced apart from the first chip. The wiring substrate may include a core portion, a first re-distribution layer on a bottom surface of the core portion, a bridge chip on a top surface of the core portion, a second re-distribution layer on the top surface of the core portion to cover the top surface of the core portion and the bridge chip, and an insulating element between the first re-distribution layer and the second re-distribution layer and enclosing the core portion. The bottom surface of the core portion and a side surface of the core portion may be spaced apart from each other in a direction perpendicular to a top surface of the first re-distribution layer.

According to an embodiment of the inventive concept, a wiring substrate may include a first re-distribution layer, a second re-distribution layer on the first re-distribution layer, and a core portion between the first re-distribution layer and the second re-distribution layer. The core portion may include a bottom surface disposed on a top surface of the first re-distribution layer and a first intermediate surface disposed on the top surface of the first re-distribution layer. A distance between the top surface of the first re-distribution layer and the core portion along the first intermediate surface, which is measured in a direction perpendicular to the top surface of the first re-distribution layer, may increase as a distance from the bottom surface increases.

According to an embodiment of the inventive concept, a wiring substrate may include a core portion, a lower re-distribution layer on a bottom surface of the core portion, an upper re-distribution layer on a top surface of the core portion, and an insulating element provided between the lower re-distribution layer and the upper re-distribution layer enclosing the core portion. The core portion may include an upper portion in contact with a bottom surface of the upper re-distribution layer and a lower portion in contact with a top surface of the lower re-distribution layer. A width of the upper portion of the core portion may be uniform, and a width of the lower portion of the core portion decreases as a distance to the top surface of the lower re-distribution layer decreases. At an interface between the upper portion and the lower portion, the width of the upper portion may be substantially equal to the width of the lower portion.

### BRIEF DESCRIPTION OF THE DRAWINGS

FIG. 1 is a sectional view illustrating a semiconductor package according to an embodiment of the inventive concept.

FIG. 2, FIG. 3, and FIG. 4 are enlarged sectional views illustrating a portion ‘A’ of FIG. 1.

FIG. 5 and FIG. 6 are sectional views illustrating a semiconductor package according to an embodiment of the inventive concept.

FIGS. 7 to 13 are sectional views illustrating a wiring substrate according to an embodiment of the inventive concept and a method of fabricating a semiconductor package including the same.

### DETAILED DESCRIPTION

The inventive concept may be implemented in various modifications and have various forms, and specific embodiments are illustrated in the drawings and described in detail in the text. It is to be understood, however, that the inventive concepts are not intended to be limited to the particular forms disclosed, but on the contrary, is intended to cover all modifications, equivalents, and alternatives falling within the spirit and scope of the inventive concept.

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

Like reference numerals or symbols refer to like elements throughout. In the drawings, the thickness, the ratio, and the dimension of the elements may be exaggerated for effective description of the technical contents.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the inventive concept. The singular forms include the plural forms unless the context clearly indicates otherwise.

Also, the terms such as “below”, “lower”, “above”, “upper” or the like, may be used in the description to describe one element's relationship to another element illustrated in the figures. It will be understood that the terms have a relative concept and may be described on the basis of the orientation depicted in the figures.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Example embodiments of the inventive concepts will now be described more fully with reference to the accompanying drawings, in which example embodiments are shown.

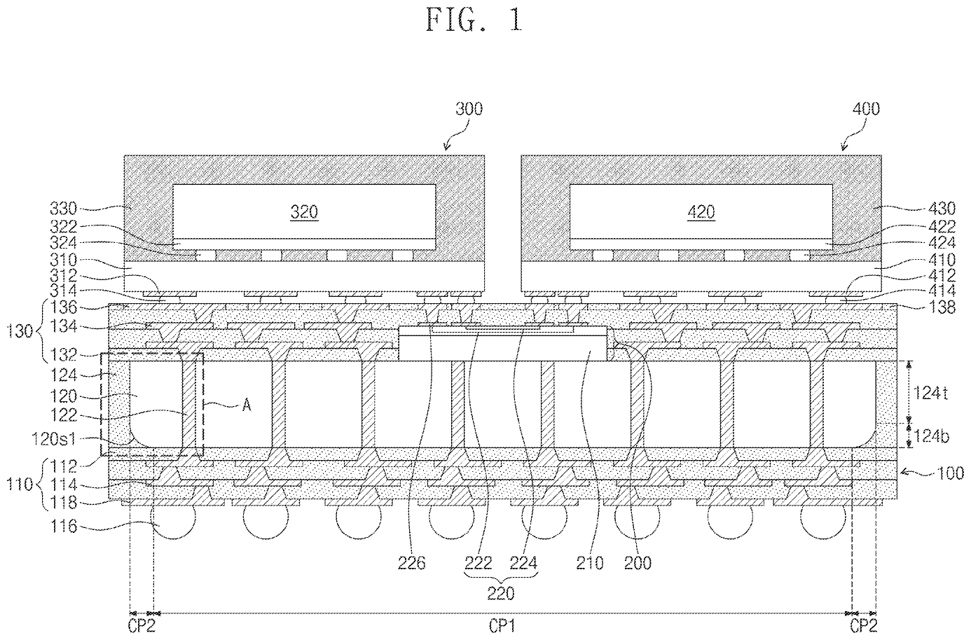

FIG. 1 is a sectional view illustrating a semiconductor package according to an embodiment of the inventive concept.

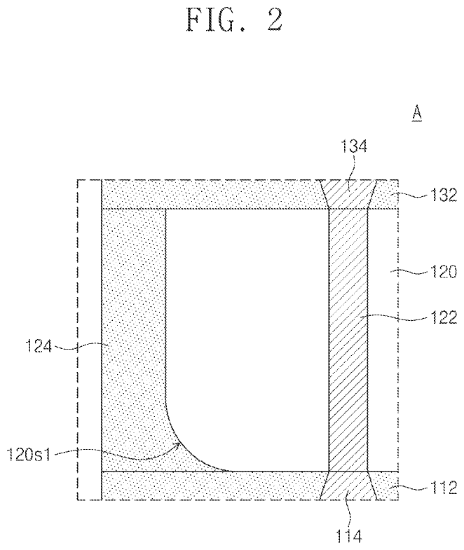

FIG. 2, FIG. 3, and FIG. 4 are enlarged sectional views illustrating a portion (e.g., portion ‘A’ of FIG. 1) of a wiring substrate according to an embodiment of the inventive concept.

Referring to FIG. 1 and FIG. 2, a wiring substrate 100 may be provided. The wiring substrate 100 may include a first re-distribution layer 110, a core portion 120, and a second re-distribution layer 130. The core portion 120 may be provided on a top surface of the first re-distribution layer 110. The second re-distribution layer 130 may be provided on a top surface of the core portion 120.

The first re-distribution layer 110 may be provided. The first re-distribution layer 110 may include first interconnection layers, which may be sequentially stacked. Each of the first interconnection layers may include a first insulating pattern 112 and a first interconnection pattern 114. The first interconnection pattern 114 of one of the first interconnection layers may be electrically connected to the first interconnection pattern 114 of another of the first interconnection layers. In the following description, the first insulating pattern 112 and the first interconnection pattern 114 will be described with reference to an instance of the first interconnection layers.

The first insulating pattern 112 may be formed of, or include, at least one of an insulating polymer or a photoimageable dielectric (PID) material. For example, the PID materials may include photoimageable polyimides, polybenzoxazole (PBO), phenol-based polymers, or benzocyclobutene-based polymers.

The first interconnection pattern 114 may be provided on a bottom surface of the first insulating pattern 112. The first interconnection pattern 114 may be a protruding pattern provided near the bottom surface of the first insulating pattern 112. The first interconnection pattern 114 may including a horizontally extended portion on the bottom surface of the first insulating pattern 112 and a via portion extending substantially vertical from the horizontally extended portion. The first interconnection pattern 114 on the bottom surface of the first insulating pattern 112 may be covered with another first insulating pattern 112 thereunder. For example, the first interconnection pattern 114 may be a pad portion or a wire portion of the first interconnection layer. In other words, the first interconnection pattern 114 may be an element that is used for horizontal redistribution in the first re-distribution layer 110. The first interconnection pattern 114 may include a conductive material. For example, the first interconnection pattern 114 may be formed of or include copper (Cu). The first interconnection pattern 114 formed of a conductive material may be an element that is used for horizontal redistribution of a signal or power in the first re-distribution layer 110.

The first interconnection pattern 114 may have a damascene structure. For example, the first interconnection pattern 114 may have the via portion that is formed near a top surface of the first interconnection pattern 114 and has a protruding shape. The via portion may be an element that vertically connects the first interconnection pattern 114 of the first interconnection layers, which are adjacent to each other. For example, the via portion may be extended from the top surface of the first interconnection pattern 114 to penetrate the first insulating pattern 112 and may be coupled to a bottom surface of the first interconnection pattern 114 of another first interconnection layer thereon. A lower portion of the first interconnection pattern 114, which is placed below the first insulating pattern 112, may be a head portion, which may be a horizontal wire or a pad, and the via portion of the first interconnection pattern 114 may be a tail portion. The first interconnection pattern 114 may have an inverted shape of letter ‘T’.

Outer terminals 116 may be provided below the first re-distribution layer 110. The outer terminals 116 may be disposed on lower pads 118, which are provided on a bottom surface of the first re-distribution layer 110. Here, the lower pads 118 may be portions of the first interconnection pattern 114, which may be exposed near the bottom surface of the first re-distribution layer 110, or may be additional pads, which may be disposed on the first insulating pattern 112 of the first re-distribution layer 110 and connected to the first interconnection pattern 114. The outer terminals 116 may include solder balls or solder bumps. The outer terminals 116 may be disposed, one-to-one, with the lower pads 118.

The core portion 120 may be disposed on the top surface of the first re-distribution layer 110. A bottom surface of the core portion 120 may be in contact with the top surface of the first re-distribution layer 110. The core portion 120 may include a first portion CP1, which may be in contact with the top surface of the first re-distribution layer 110, and a second portion CP2, which may be provided to enclose the first portion CP1 when viewed in a plan view. For example, a bottom surface of the first portion CP1 may be the bottom surface of the core portion 120. A side surface of the second portion CP2 may be a side surface of the core portion 120. The side surface of the second portion CP2 may be in contact with a side surface of the first portion CP1. The first portion CP1 may be a center portion of the core portion 120, and the second portion CP2 may be an edge portion of the core portion 120.

The top surface of the core portion 120 may be extend from the side surface of the core portion 120 in a direction parallel to the top surface of the first re-distribution layer 110. The bottom surface of the core portion 120 may be spaced apart from the side surface of the core portion 120 in a direction perpendicular to the top surface of the first re-distribution layer 110. The core portion 120 may include a first intermediate surface 120s1 connecting the bottom surface of the core portion 120 to the side surface of the core portion 120. Here, the first intermediate surface 120s1 may correspond to a bottom surface of the second portion CP2. In other words, the bottom surface of the second portion CP2 may connect the side surface of the second portion CP2 to the bottom surface of the first portion CP1. The first intermediate surface 120s1 may be a rounded surface. As an example, the first intermediate surface 120s1 may include a convexly curved surface. Accordingly, when measured in the direction perpendicular to the top surface of the first re-distribution layer 110, a distance between the top surface of the first re-distribution layer 110 and the bottom surface of the second portion CP2 may increase as a distance from the first portion CP1 increases.

In an embodiment, the first intermediate surface 120s1 may be linear. For example, the first intermediate surface 120s1 may be a flat surface connecting the side surface of the core portion 120 to the bottom surface of the core portion 120, as shown in FIG. 3. The first intermediate surface 120s1 may be inclined at an angle to both of the side and bottom surfaces of the core portion 120. An angle θ₁ between the bottom surface of the core portion 120 and the first intermediate surface 120s1 and an angle θ₂ between the first intermediate surface 120s1 and the side surface of the core portion 120 may be obtuse angles.

In an embodiment, the first intermediate surface 120s1 may be composed of a plurality of surfaces. The first intermediate surface 120s1 may be composed of a plurality of linear surfaces. For example, as shown in FIG. 4, the first intermediate surface 120s1 may include a first surface P1 between the side surface of the core portion 120 and the bottom surface of the core portion 120, and a second surface P2 between the side surface of the core portion 120 and the first surface P1. The first surface P1 may be inclined at an angle to both of the bottom surface of the core portion 120 and the second surface P2. The second surface P2 may be inclined at an angle to both of the side surface of the core portion 120 and the first surface P1. Here, an angle θ₃ between the bottom surface of the core portion 120 and the first surface P1, an angle θ₄ between the first surface P1 and the second surface P2, and an angle θ₅ between the second surface and the side surface of the core portion 120 may be obtuse angles.

FIG. 4 illustrates an example in which the bottom surface of the core portion 120 is connected to the side surface of the core portion 120 by two surfaces, but the inventive concepts are not limited to this example. A plurality of surfaces may be additionally formed between the first surface P1 and the second surface P2, and in this case, an angle between the surfaces may be obtuse.

Referring to FIGS. 1 to 4, the core portion 120 may have the first intermediate surface 120s1 connecting the bottom surface of the core portion 120 to the side surface of the core portion 120. Here, the first intermediate surface 120s1 may be a rounded surface, a flat surface, or a plurality of surfaces. In a case that the first intermediate surface 120s1 includes a plurality of lateral surfaces, adjacent ones of the lateral surfaces may meet each other with an obtuse angle. The first intermediate surface 120s1 may include a rounded surface and a flat surface. Accordingly, a lower portion of the core portion 120 may be provided to have a structure capable of alleviating a vertical stress on the side surface of the core portion 120. In an embodiment, a load may be concentrated on the lower portion of the core portion 120. The lower portion of the core portion 120 may improve the mechanical durability of the core portion 120. The following description will be given with reference to an embodiment of FIG. 1.

The core portion 120 may include a core pattern, when viewed in a plan view. The core portion 120 may include an insulating material. For example, the core portion 120 may be formed of, or include glass.

The core portion 120 may include core penetration vias 122 vertically penetrating the core portion 120. The core penetration vias 122 may extend from the top surface of the core portion 120 toward the bottom surface of the core portion 120. The core penetration vias 122 may be exposed to the outside of the core portion 120 near the top surface and the bottom surface of the core portion 120. The core penetration vias 122 may include a conductive material. For example, the core penetration vias 122 may be formed of, or include at least one of a metallic material such as copper (Cu), aluminum (Al) or tungsten (W).

The second re-distribution layer 130 may be provided on the top surface of the core portion 120. The second re-distribution layer 130 may cover the top surface of the core portion 120. The second re-distribution layer 130 may include one or more second interconnection layers, which may be sequentially stacked on the top surface of the core portion 120. Each of the second interconnection layers may include a second insulating pattern 132 and a second interconnection pattern 134. The second interconnection pattern 134 of one of the second interconnection layers may be electrically connected to the second interconnection pattern 134 of an adjacent second interconnection layer. In the following description, the second insulating pattern 132 and the second interconnection pattern 134 will be described with reference to an instance of the second interconnection layers.

The second insulating pattern 132 may include at least one of an insulating polymer or a photoimageable polymer (PID). For example, the photoimageable polymers may include at least one of a photoimageable polyimide (PI), polybenzoxazole (PBO), a phenol-based polymer, or a benzocyclobutene-based polymer.

The second interconnection pattern 134 may be provided on a top surface of the second insulating pattern 132. The second interconnection pattern 134 may be a protruding pattern provided near the top surface of the second insulating pattern 132. The second interconnection pattern 134 may include a horizontally extended portion on the top surface of the second insulating pattern 132 and a via portion extending substantially vertical from the horizontally extended portion. The second interconnection pattern 134 on the top surface of the second insulating pattern 132 may be covered with another second insulating pattern 132 thereon. For example, the second interconnection pattern 134 may be a pad portion or a wire portion of the second interconnection layer. In other words, the second interconnection pattern 134 may be an element that is used for horizontal redistribution in the second re-distribution layer 130. The second interconnection pattern 134 may include a conductive material. For example, the second interconnection pattern 134 may be formed of, or include copper (Cu). The second interconnection pattern 134 formed of a conductive material may be an element that is used for horizontal redistribution of a signal or power in the second re-distribution layer 130.

The second interconnection pattern 134 may have a damascene structure. For example, the second interconnection pattern 134 may have the via portion that is formed near a bottom surface of the second interconnection pattern 134 and has a protruding shape. The via portion may be an element that vertically connects the second interconnection pattern 134 of the second interconnection layers, which are adjacent to each other. For example, the via portion may be extended from a bottom surface of the second interconnection pattern 134 to penetrate the second insulating pattern 132 and may be coupled to a top surface of the second interconnection pattern 134 of another second interconnection layer thereunder. In other words, an upper portion of the second interconnection pattern 134, which is placed on the second insulating pattern 132, may be a head portion, which may be used as a horizontal wire or a pad, and the via portion of the second interconnection pattern 134 may be a tail portion. The second interconnection pattern 134 may have a shape of the letter ‘T’.

The second interconnection patterns 134 may be electrically connected to the first interconnection patterns 114, respectively, through the core penetration vias 122. Top surfaces of the core penetration vias 122 may be respectively connected to bottom surfaces of the second interconnection patterns 134 in the lowermost one of the second interconnection layers, and bottom surfaces of the core penetration vias 122 may be respectively connected to top surfaces of the first interconnection patterns 114 in the uppermost one of the first interconnection layers. That is, the first re-distribution layer 110 and the second re-distribution layer 130 may be electrically connected to each other through the core penetration vias 122.

Upper pads 136 may be provided on a top surface of the second re-distribution layer 130. The upper pads 136 may be portions of the second interconnection pattern 134, which may be exposed from the second insulating pattern 132 of the second re-distribution layer 130, or may be additional pads, which may be disposed on the second insulating pattern 132 of the second re-distribution layer 130 and may be connected to the second interconnection pattern 134. The upper pads 136 may include a conductive material. For example, the upper pads 136 may be formed of, or include copper (Cu).

A substrate protection layer 138 may be provided on the top surface of the second re-distribution layer 130. The substrate protection layer 138 may cover an uppermost second interconnection layer of the second interconnection layers. The substrate protection layer 138 may be provided to cover the second insulating pattern 132 and enclose the upper pads 136. The upper pads 136 may be exposed to the outside of the substrate protection layer 138 near a top surface of the substrate protection layer 138. The substrate protection layer 138 may include at least one of an insulating polymer or a photoimageable polymer. In an embodiment, the substrate protection layer 138 may be omitted.

An insulating element 124 may be provided between the first re-distribution layer 110 and the second re-distribution layer 130 to enclose the core portion 120. A bottom surface of the insulating element 124 may be in contact with the top surface of the first re-distribution layer 110. A top surface of the insulating element 124 may be in contact with a bottom surface of the second re-distribution layer 130. The insulating element 124 may include a lower insulating element 124b and an upper insulating element 124t. The lower insulating element 124b may enclose a lower portion of the core portion 120. The upper insulating element 124t may enclose an upper portion of the core portion 120. The upper portion of the core portion 120 may be a portion of the core portion 120 that is in contact with the bottom surface of the second re-distribution layer 130. The lower portion of the core portion 120 may be a remaining portion of the core portion 120, excluding the upper portion. The lower portion of the core portion 120 may be in contact with the top surface of the first re-distribution layer 110. The lower portion of the core portion 120 may include the bottom surface of the core portion 120 and the first intermediate surface 120s1.

The upper insulating element 124t may be provided to enclose the side surface of the core portion 120. The upper insulating element 124t may have a uniform width. In the present specification, the term ‘width’ of an element refers to a distance between two opposite side surfaces of an element measured in a direction parallel to the top surface of the first re-distribution layer 110. That is, the upper portion of the core portion 120 may have a uniform width.

The lower insulating element 124b may be provided to enclose the first intermediate surface 120s1. A width of the lower insulating element 124b may increase as a distance to the top surface of the first re-distribution layer 110 decreases. That is, at an interface between the upper portion and the lower portion, the width of the upper portion may be equal to the width of the lower portion at a top surface thereof, and the width of the lower portion may decrease as a distance to the top surface of the first re-distribution layer 110 decreases. An interface between the lower insulating element 124b and the first re-distribution layer 110 may be located at the same level as the bottom surface of the core portion 120. In an embodiment, although not shown, the interface between the lower insulating element 124b and the first re-distribution layer 110 may be located at a level higher than the bottom surface of the core portion 120. In other words, the top surface of the first re-distribution layer 110 may protrude toward the first intermediate surface 120s1.

The insulating element 124 may include an insulating material. For example, the insulating element 124 may include an epoxy resin. In detail, the insulating element 124 may include an epoxy resin film. As an example, the insulating element 124 may include an insulating film such as AJINOMOTO BUILD-UP FILM® (ABF).

According to an embodiment of the inventive concept, the insulating element 124 may be provided between the first re-distribution layer 110 and the second re-distribution layer 130 to enclose the core portion 120, and the side surface of the core portion 120 may be protected from an external force. Thus, a wiring substrate with improved mechanical durability and a semiconductor package including the same may be provided.

A bridge chip 200 may be provided in the second re-distribution layer 130. The bridge chip 200 may be provided on the top surface of the core portion 120. The bridge chip 200 in the second re-distribution layer 130 may be covered with the second insulating pattern 132. Sides of the bridge chip 200 in the second re-distribution layer 130 may be disposed adjacent to sides of one or more layers of the second insulating pattern 132. One or more layers of the second insulating pattern 132 may be disposed on the bridge chip 200.

The bridge chip 200 may be provided on the core portion 120 in a face-up manner. Although not shown, the bridge chip 200 may be attached to the top surface of the core portion 120 using an adhesive layer. The bridge chip 200 may include a bridge substrate 210 and a bridge circuit layer 220.

The bridge substrate 210 may include a semiconductor substrate. For example, the bridge substrate 210 may be a silicon substrate, a silicon-on-insulator (SOI) substrate, a germanium (Ge) substrate, a germanium-on-insulator (GOI) substrate, a silicon-germanium (SiGe) substrate, a group III-V semiconductor substrate, or a substrate including an epitaxial film formed by a selective epitaxial growth (SEG) process.

The bridge circuit layer 220 may be provided on a top surface of the bridge substrate 210. For example, the bridge circuit layer 220 may include a bridge insulating pattern 222 and a bridge circuit pattern 224, which may be formed on the top surface of the bridge substrate 210.

The bridge insulating pattern 222 may include an insulating material. The bridge insulating pattern 222 may be formed of, or include at least one of silicon oxide (SiO), silicon nitride (SiN), silicon oxynitride (SiON), silicon carbonitride (SiCN), or insulating polymers. The bridge insulating pattern 222 may include one or more insulating layers, and the bridge circuit pattern 224 may be an interconnection pattern, which may be provided in the insulating layers.

The bridge circuit pattern 224 may be provided in the bridge insulating pattern 222. The bridge circuit pattern 224 may be configured to electrically connect various semiconductor devices, which may be mounted on the core portion 120, to each other. The bridge circuit pattern 224 may include a conductive material. For example, the bridge circuit pattern 224 may be formed of, or include copper (Cu) or aluminum (Al).

Bridge pads 226 may be disposed on a top surface of the bridge circuit layer 220. The bridge pads 226 may be disposed in different regions of the bridge chip 200. As an example, some of the bridge pads 226 may be disposed in a first region, and the remaining ones of the bridge pads 226 may be disposed in a second region. Here, the first region may be a region on a bottom surface of a first device 300, and the second region may be a region on a bottom surface of a second device. The bridge pads 226, which are placed in different regions, may be connected to each other by the bridge circuit pattern 224.

The afore-described structure is an example of the bridge chip 200, but the inventive concepts are not limited to this example. In an embodiment, the bridge chip 200 may be omitted.

The first device 300 may be provided on the wiring substrate 100. The first device 300 may include a first substrate 310, a first semiconductor chip 320, and a first mold layer 330. The first substrate 310, the first semiconductor chip 320, and the first mold layer 330 may be sequentially formed.

The first substrate 310 may be a printed circuit board (PCB). In an embodiment, the first substrate 310 may be a re-distribution layer. The first substrate 310 may include first pads 312, which may be disposed on a bottom surface of the first substrate 310.

The first semiconductor chip 320 may be disposed on the first substrate 310. The first semiconductor chip 320 may include a first circuit layer 322, which may be provided as a lower portion of the first semiconductor chip 320. The first circuit layer 322 may include one or more integrated circuits, and here, the integrated circuits may include a memory circuit, a logic circuit, or combinations thereof. In other words, the first semiconductor chip 320 may be a memory chip or logic chip.

The first semiconductor chip 320 may be mounted on the first substrate 310. For example, first chip terminals 324, which may be electrically connected to the first circuit layer 322, may be provided on a bottom surface of the first semiconductor chip 320. Although not shown, the first chip terminals 324 may be coupled to pads, which may be provided on a top surface of the first substrate 310. The first semiconductor chip 320 may be coupled to the pads of the first substrate 310 through the first chip terminals 324. FIG. 1 illustrates an example, in which the first semiconductor chip 320 may be mounted on the first substrate 310 in a flip chip manner, but the inventive concepts are not limited to this example. For example, the first semiconductor chip 320 may be mounted on the first substrate 310 in a wire bonding manner.

The first mold layer 330 may be provided on the first substrate 310 to cover the first semiconductor chip 320. The first mold layer 330 may encapsulate the first semiconductor chip 320. The first mold layer 330 may be formed of, or include at least one insulating polymer (e.g., epoxy-based polymers).

The first device 300 may be mounted on the top surface of the second re-distribution layer 130. First connection terminals 314 may be electrically connected to the first pads 312. The first connection terminals 314 may be coupled to the upper pads 136. The first pads 312 or the first device 300 may be connected to the wiring substrate 100 through the first connection terminals 314. For example, the first device 300 may be connected to the upper pads 136 through the first pads 312 and the first connection terminals 314.

FIG. 1 illustrates an example of the first device 300, but the inventive concepts are not limited to this example. The first device 300 may be a semiconductor package with a plurality of semiconductor chips. In an embodiment, the first device 300 may be a single semiconductor chip or a single semiconductor die. In an embodiment, the first device 300 may include various interconnection devices, such as a connector, an input/output device, or a substrate, which may be used for electric connection to the outside.

A second device 400 may be provided on the wiring substrate 100. The second device 400 may be horizontally spaced apart from the first device 300. The second device 400 may include a second substrate 410, a second semiconductor chip 420, and a second mold layer 430. The second substrate 410, the second semiconductor chip 420, and the second mold layer 430 may be sequentially formed.

The second substrate 410 may be a printed circuit board (PCB). In an embodiment, the second substrate 410 may be a re-distribution layer. The second substrate 410 may include second pads 412 disposed on a bottom surface of the second substrate 410.

The second semiconductor chip 420 may be disposed on the second substrate 410. The second semiconductor chip 420 may include a second circuit layer 422, which may be provided as a lower portion of the second semiconductor chip 420. The second circuit layer 422 may include one or more integrated circuits, and here, the integrated circuits may include a memory circuit, a logic circuit, or combinations thereof. In other words, the second semiconductor chip 420 may be a memory chip or a logic chip.

The second semiconductor chip 420 may be mounted on the second substrate 410. For example, second chip terminals 424, which are electrically connected to the second circuit layer 422, may be provided on a bottom surface of the second semiconductor chip 420. Although not shown, the second chip terminals 424 may be coupled to pads, which may be provided on a top surface of the second substrate 410. The second semiconductor chip 420 may be coupled to the pads through the second chip terminals 424. FIG. 1 illustrates an example, in which the second semiconductor chip 420 may be mounted on the second substrate 410 in a flip chip manner, but the inventive concepts are not limited to this example. For example, the second semiconductor chip 420 may be mounted on the second substrate 410 in a wire bonding manner.

The second mold layer 430 may be provided on the second substrate 410 to cover the second semiconductor chip 420. The second mold layer 430 may encapsulate the second semiconductor chip 420. The second mold layer 430 may be formed of, or include at least one of insulating polymer (e.g., epoxy-based polymers).

The second device 400 may be mounted on the top surface of the second re-distribution layer 130. For example, second connection terminals 414 may be provided on the second pads 412. The second connection terminals 414 may be coupled to the upper pads 136. The second pads 412 or the second device 400 may be connected to the wiring substrate 100 through the second connection terminals 414. The second device 400 may be connected to the wiring substrate 100 through the second pads 412 and the second connection terminals 414.

FIG. 1 illustrates an example of the second device 400, but the inventive concepts are not limited to this example. The second device 400 may be a semiconductor package with a plurality of semiconductor chips. In an embodiment, the second device 400 may be a single semiconductor chip or a single semiconductor die. In an embodiment, the second device 400 may include various interconnection devices, such as a connector, an input/output device, or a substrate, which may be used for electric connection to the outside.

The semiconductor package according to an embodiment of the inventive concept may have the afore-described structure(s). According to an embodiment of the inventive concept, the first intermediate surface 120s1 connecting the side surface of the core portion 120 to the bottom surface of the core portion 120 may be provided to have a shape capable of alleviating a vertical stress on the side surface of the core portion 120. Accordingly, the mechanical durability of the core portion 120 may be improved. In addition, the insulating element 124 may be formed to enclose the core portion 120, and the core portion 120 may be protected from an external force. Thus, it may be possible to provide a wiring substrate with improved mechanical durability and a semiconductor package including the same.

In the description of embodiments to be explained below, an element previously described with reference to FIG. 1 may be identified by the same reference number without repeating an overlapping description thereof, for concise description.

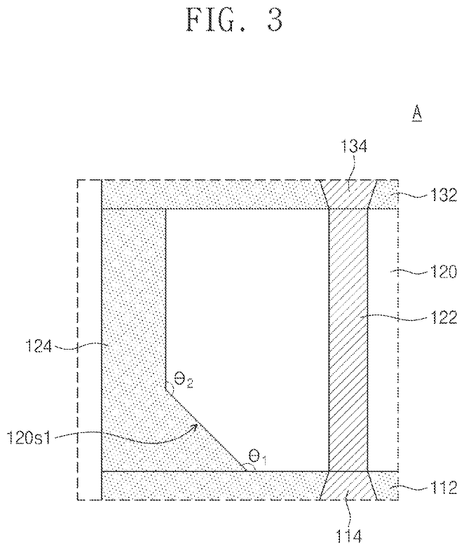

FIG. 5 is a sectional view illustrating a semiconductor package according to an embodiment of the inventive concept.

Referring to FIG. 5, a semiconductor package may be provided.

A bottom surface of the core portion 120 may be spaced apart from the side surface of the core portion 120 in a direction perpendicular to the top surface of the first re-distribution layer 110. The core portion 120 may include the first intermediate surface 120s1 connecting the bottom surface of the core portion 120 to the side surface of the core portion 120. The first intermediate surface 120s1 may be substantially the same as the first intermediate surface 120s1 previously described with reference to FIG. 1 and FIG. 2.

A first insulating element 126 may be provided between the first re-distribution layer 110 and the second re-distribution layer 130 to enclose the side surface of the core portion 120 and the first intermediate surface 120s1. An interface between the first insulating element 126 and the first re-distribution layer 110 may be located at a level higher than the bottom surface of the core portion 120. That is, in a region adjacent to the bottom surface of the core portion 120, at least a portion of the top surface of the first re-distribution layer 110 may protrude toward the first intermediate surface 120s1. In an embodiment, although not shown, the interface between the first insulating element 126 and the first re-distribution layer 110 may be located at the same level as the bottom surface of the core portion 120. In other words, the top surface of the first re-distribution layer 110 may be linear and may not protrude toward the first intermediate surface 120s1.

The top surface of the core portion 120 and the side surface of the core portion 120 may be spaced apart from each other in a direction perpendicular to the bottom surface of the second re-distribution layer 130. The core portion 120 may include a second intermediate surface 120s2 connecting the top surface of the core portion 120 to the side surface of the core portion 120. The second intermediate surface 120s2 may be a rounded surface. As an example, the first intermediate surface 120s1 and the second intermediate surface 120s2 may be convexly curved surfaces.

A second insulating element 128 may be provided between the first re-distribution layer 110 and the second re-distribution layer 130 and on the top surface of the first insulating element 126 to enclose the second intermediate surface 120s2. An interface between the second insulating element 128 and the second re-distribution layer 130 may be located at a level lower than the top surface of the core portion 120. That is, in a region adjacent to the top surface of the core portion 120, at least a portion of the bottom surface of the second re-distribution layer 130 may protrude toward the second intermediate surface 120s2. In an embodiment, although not shown, the interface between the second insulating element 128 and the second re-distribution layer 130 may be located at the same level as the top surface of the core portion 120. That is, the bottom surface of the second re-distribution layer 130 may be linear and may not protrude toward the second intermediate surface 120s2.

A side surface of the first insulating element 126 may be aligned to a side surface of the first re-distribution layer 110. A side surface of the second insulating element 128 may be aligned to a side surface of the second re-distribution layer 130. The side surface of the first re-distribution layer 110 may be aligned to the side surface of the second re-distribution layer 130. An interface between the first insulating element 126 and the second insulating element 128 may be in contact with the second intermediate surface 120s2. The interface between the first insulating element 126 and the second insulating element 128 may be sequentially connected to the second intermediate surface 120s2 and the top surface of the core portion 120. The first insulating element 126 and the second insulating element 128 may include an insulating material. For example, the first insulating element 126 and second insulating element 128 may be formed of, or include an epoxy resin.

According to an embodiment of the inventive concept, the first intermediate surface 120s1 may be formed to connect the bottom surface of the core portion 120 to the side surface of the core portion 120, and the second intermediate surface 120s2 may be formed to connect the top surface of the core portion 120 to the side surface of the core portion 120. Here, the first intermediate surface 120s1 and the second intermediate surface 120s2 may be composed of rounded surfaces or a plurality of surfaces meeting each other with an obtuse angle. Accordingly, a lower portion of the core portion 120 may be deformed to alleviate a vertical stress on the side surface of the core portion 120, and this may increase the mechanical durability of the core portion 120. According to an embodiment, a load may be concentrated on the lower portion of the core portion 120, and the lower portion of the core portion 120 may be deformed to alleviate a vertical stress on the side surface of the core portion 120, and this may increase the mechanical durability of the core portion 120. In addition, since the first insulating element 126 enclosing the side surface of the core portion 120 and at least a portion of the first intermediate surface 120s1 and the second insulating element 128 enclosing at least a portion of the second intermediate surface 120s2 may be provided between the first re-distribution layer 110 and the second re-distribution layer 130, it may be possible to protect the side surface of the core portion 120 from an external force. Thus, a wiring substrate with improved mechanical durability and a semiconductor package including the same may be provided.

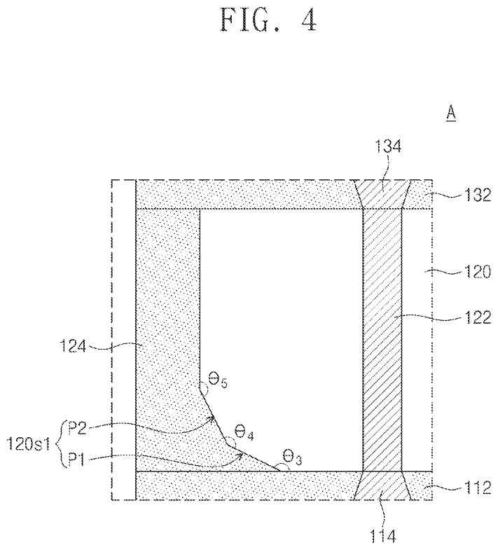

FIG. 6 is a sectional view illustrating a semiconductor package according to an embodiment of the inventive concept.

Referring to FIG. 6, the wiring substrate 100 may be provided. The wiring substrate 100 may be substantially the same or similar as the wiring substrate 100 previously described with reference to FIG. 1. For example, the wiring substrate 100 may have the core portion 120, the first re-distribution layer 110, and the second re-distribution layer 130 and may include the bridge chip 200 disposed in the second re-distribution layer 130.

A third semiconductor chip 500 may be provided on the wiring substrate 100. The bottom surface of the third semiconductor chip 500 may be an active surface. In other words, the bottom surface of the third semiconductor chip 500 may be a front surface. The third semiconductor chip 500 may be provided on the second re-distribution layer 130 in a face-down manner. The third semiconductor chip 500 may include a third semiconductor substrate 510 and a third circuit layer 520.

The third semiconductor chip 500 may include the third semiconductor substrate 510. The third semiconductor substrate 510 may include a semiconductor material. As an example, the third semiconductor substrate 510 may be formed of, or include silicon (Si). An integrated device or integrated circuits may be formed on a bottom surface of the third semiconductor substrate 510.

The third circuit layer 520 may be provided on the bottom surface of the third semiconductor substrate 510. The third circuit layer 520 may include a third insulating pattern 522 and a third circuit pattern 524 provided in the third insulating pattern 522. The third insulating pattern 522 may cover the integrated device or the integrated circuits disposed on the bottom surface of the third semiconductor chip 500. The third circuit pattern 524 may be coupled to the integrated device or the integrated circuits formed on the third semiconductor substrate 510. The third circuit layer 520 may include a logic circuit. In other words, the third semiconductor chip 500 may be a logic chip. In an embodiment, the third circuit layer 520 may include a memory circuit. For example, the third semiconductor chip 500 may be a memory chip, such as a DRAM, SRAM, MRAM or FLASH memory chip.

The third semiconductor chip 500 may be mounted on the second re-distribution layer 130. For example, the third semiconductor chip 500 may be coupled to the upper pads 136 and the bridge pads 226, which may be placed on a third region, through third connection terminals 530. The third region may be a region on the bottom surface of the third semiconductor chip 500. The third semiconductor chip 500 may be electrically connected to the second re-distribution layer 130 and the bridge chip 200 through the third connection terminals 530. The third connection terminals 530 may be provided between the upper pads 136 and the bridge pads 226, which may be placed on the third region, and third pads 526, which may be provided on the bottom surface of the third semiconductor chip 500. Here, the third pads 526 may be portions of the third circuit pattern 524, which are exposed from the third insulating pattern 522 of the third circuit layer 520, or may be additional pads, which are disposed on the third insulating pattern 522 of the third circuit layer 520 and are connected to the third circuit pattern 524. Since the third semiconductor chip 500 may be mounted on the second re-distribution layer 130 using the third connection terminals 530, the bottom surface of the third semiconductor chip 500 may be spaced apart from the second re-distribution layer 130.

A first under-fill layer 540 may be provided between the top surface of the second re-distribution layer 130 and the bottom surface of the third semiconductor chip 500. The first under-fill layer 540 may be provided in a space between the second re-distribution layer 130 and the third semiconductor chip 500. The first under-fill layer 540 may fill the space between the second re-distribution layer 130 and the third semiconductor chip 500 and may enclose the upper pads 136, the third pads 526, the bridge pads 226, and the third connection terminals 530 on the third region.

A chip stack CS may be provided on the wiring substrate 100. The chip stack CS on the wiring substrate 100 may be horizontally spaced apart from the third semiconductor chip 500. The chip stack CS may include a base chip 600, fourth semiconductor chips 700, and a third mold layer 740. The fourth semiconductor chips 700 may be stacked on the base chip 600. The third mold layer 740 may enclose the fourth semiconductor chips 700. Hereinafter, the structure of the chip stack CS will be described in more detail below.

The base chip 600 may include a base substrate 610. The base substrate 610 may be a semiconductor substrate. For example, the base substrate 610 may be a wafer-level semiconductor substrate, which may be formed of a semiconductor material, such as silicon (Si). A bottom surface of the base chip 600 may be an active surface. In detail, an integrated device or integrated circuits may be formed on a bottom surface of the base substrate 610.

The base chip 600 may include a base circuit layer 620 and a base penetration via 612.

The base circuit layer 620 may be provided on the bottom surface of the base chip 600. The base circuit layer 620 may include the integrated device or the integrated circuit. For example, the base circuit layer 620 may be a memory circuit. In other words, the base chip 600 may be a memory chip, such as a DRAM, SRAM, MRAM or FLASH memory chip. In an embodiment, the base circuit layer 620 may be a logic circuit. In this case, the base chip 600 may be a logic chip. The base penetration via 612 may penetrate the base chip 600 in a direction substantially perpendicular to the top surface of the second re-distribution layer 130. The base penetration via 612 and the base circuit layer 620 may be electrically connected to each other.

The fourth semiconductor chip 700 may be provided on the base chip 600. A width of the fourth semiconductor chip 700 may be smaller than a width of the base chip 600. The width of the fourth semiconductor chip 700 and the width of the base chip 600 may be measured in a direction parallel to the top surface of the second re-distribution layer 130. The fourth semiconductor chip 700 may include a fourth semiconductor substrate 710, a fourth circuit layer 720, and a penetration via 712. The fourth semiconductor substrate 710 may be a semiconductor substrate. In an embodiment, the fourth semiconductor substrate 710 may be formed of, or include silicon (Si). The fourth circuit layer 720, which may be disposed on a bottom surface of the fourth semiconductor substrate 710, and may include a memory circuit. That is, the fourth semiconductor chip 700 may be a memory chip, such as a DRAM, SRAM, MRAM or FLASH memory chip. The penetration via 712 may penetrate the fourth semiconductor chip 700 in a direction substantially perpendicular to the top surface of the second re-distribution layer 130. The penetration via 712 and the fourth circuit layer 720 may be electrically connected to each other. A bottom surface of the fourth semiconductor chip 700 may be an active surface. Connection bumps 730 may be provided on the bottom surface of the fourth semiconductor chip 700. The connection bumps 730 may be provided between the base chip 600 and the fourth semiconductor chip 700. The connection bumps 730 may electrically connect the base chip 600 to the fourth semiconductor chip 700.

In an embodiment, a plurality of fourth semiconductor chips 700 may be provided. For example, a plurality of fourth semiconductor chips 700 may be stacked on the base chip 600. In an embodiment, the number of the fourth semiconductor chips 700 stacked may be between about 8 to 32. The connection bumps 730 may be respectively provided between the fourth semiconductor chips 700. Here, a topmost chip of the fourth semiconductor chips 700 may not include the penetration via 712. In addition, the topmost chip of the fourth semiconductor chips 700 may be thicker than the remaining ones of the fourth semiconductor chips 700 disposed below the topmost chip.

Although not shown, an adhesive layer may be provided between the fourth semiconductor chips 700. The adhesive layer may include a non-conductive film (NCF). The adhesive layer may be interposed between the connection bumps 730, which may be disposed between the fourth semiconductor chips 700. The adhesive layer may prevent an electric short from being formed between the connection bumps 730.

The third mold layer 740 may be disposed on a top surface of the base chip 600. The third mold layer 740 may cover the base chip 600. The third mold layer 740 may be provided to enclose the fourth semiconductor chips 700. For example, the third mold layer 740 may be disposed along sidewalls of the fourth semiconductor substrate 710. A top surface of the third mold layer 740 may be coplanar with a top surface of the uppermost one of the fourth semiconductor chips 700. The uppermost one of the fourth semiconductor chips 700 may be exposed to the outside of the third mold layer 740 near the top surface of the third mold layer 740. The third mold layer 740 may include an insulating polymer material. For example, the third mold layer 740 may be formed of, or include an epoxy molding compound (EMC).

The chip stack CS may be provided to have the afore-described structure(s). The chip stack CS may be mounted on the second re-distribution layer 130. For example, the chip stack CS may be coupled to the upper pads 136 on a fourth region and the bridge pads 226 on the fourth region through fourth connection terminals 750 on the bottom surface of the base chip 600. The fourth region may be a region on the bottom surface of the base chip 600. The fourth semiconductor chip 700 may be electrically connected to the second re-distribution layer 130 and the bridge chip 200 through the fourth connection terminals 750. The fourth connection terminals 750 may be provided between the upper pads 136 and the bridge pads 226, which may be placed on the fourth region, and fourth pads 626, which may be provided on the bottom surface of the base chip 600. Here, the fourth pads 626 may be portions of the circuit pattern, which may be exposed from the insulating pattern of the base circuit layer 620, or may be additional pads, which may be disposed on the insulating pattern of the base circuit layer 620 and may be connected to the circuit pattern. Since the chip stack CS may be mounted on the second re-distribution layer 130 using the fourth connection terminals 750, a bottom surface of the chip stack CS may be spaced apart from the second re-distribution layer 130.

A second under-fill layer 760 may be provided between the second re-distribution layer 130 and the chip stack CS. The second under-fill layer 760 may be provided in a space between the second re-distribution layer 130 and the base chip 600. The second under-fill layer 760 may be provided to fill a space between the second re-distribution layer 130 and the base chip 600 and may enclose the upper pads 136, the fourth pads 626, the bridge pads 226, and the fourth connection terminals 750 on the fourth region.

A fourth mold layer 770 may be disposed on the top surface of the second re-distribution layer 130. The fourth mold layer 770 may be provided to enclose the fourth semiconductor chip 700, the first under-fill layer 540, the chip stack CS, and the second under-fill layer 760. In an embodiment, a top surface of the fourth mold layer 770 may be coplanar with a top surface of the uppermost one of the fourth semiconductor chips 700 of the chip stack CS and a top surface of the third mold layer 740. In an embodiment, the fourth semiconductor chip 700 and the third mold layer 740 may be exposed to the outside near the top surface of the fourth mold layer 770. The fourth mold layer 770 may include an insulating polymer material. For example, the fourth mold layer 770 may be formed of, or include an epoxy molding compound (EMC).

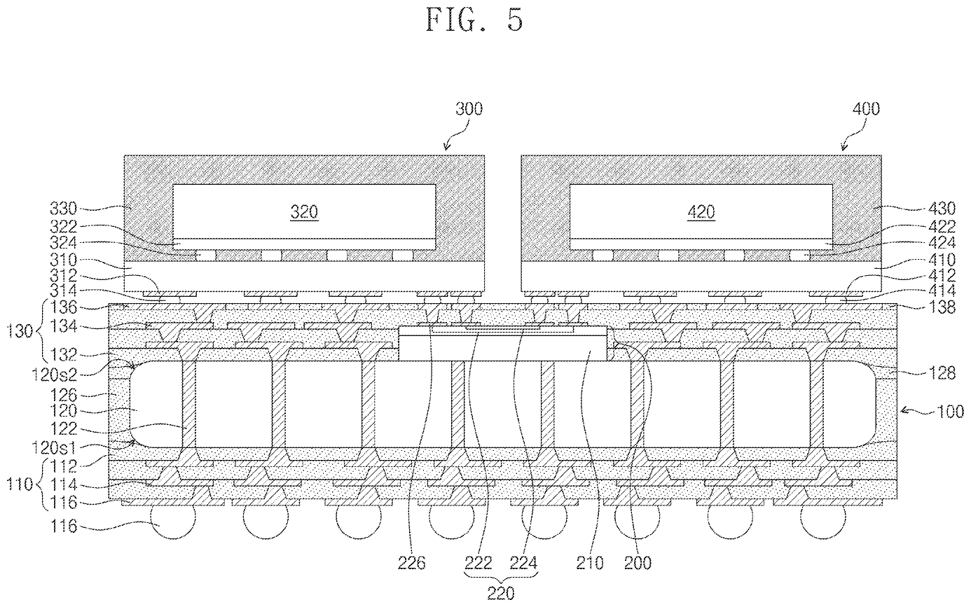

FIGS. 7 to 13 are sectional views illustrating a method of fabricating a semiconductor package, according to an embodiment of the inventive concept.

Referring to FIG. 7, a carrier 800 may be provided. The core portion 120 may be provided on a top surface of the carrier 800. The core penetration vias 122 may be formed in the core portion 120. For example, holes may be formed in the core portion 120 and filled with a conductive material, forming the core penetration vias 122.

A first dicing process may be performed on the core portion 120. The first dicing process may be performed adjacent to a first cutting line CL1. The first dicing process may be performed to partially remove an upper portion of the core portion 120. Accordingly, a trench TR may be formed on the top surface of the core portion 120. The trench TR may have a substantially concave shape in the top surface of the core portion 120.

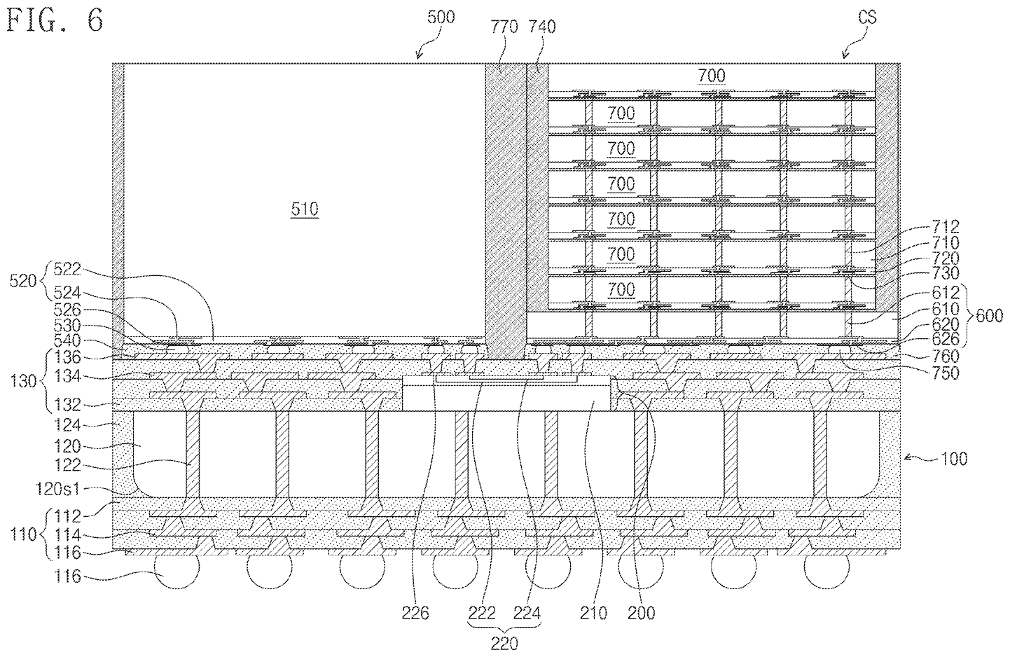

Referring to FIG. 8, a second dicing process may be performed on the core portion 120 in the resulting structure of FIG. 7. The second dicing process may be performed along a second cutting line CL2. The second cutting line CL2 may be located between adjacent ones of the first cutting lines CL1. For example, the second cutting line CL2 may be perpendicular to the top surface of the core portion 120 and overlapping the trench TR. The second dicing process may remove a portion of the core portion 120 overlapping the trench TR and exposing the top surface of the carrier 800 below the core portion 120. As a result of the second dicing process, a plurality of core portions 120, which are spaced apart from each other, may be formed. Accordingly, opposite side surfaces of the core portions 120 may be formed. In addition, the first intermediate surface 120s1 may be formed and may connect the side surface of the core portion 120 to the top surface of the core portion 120.

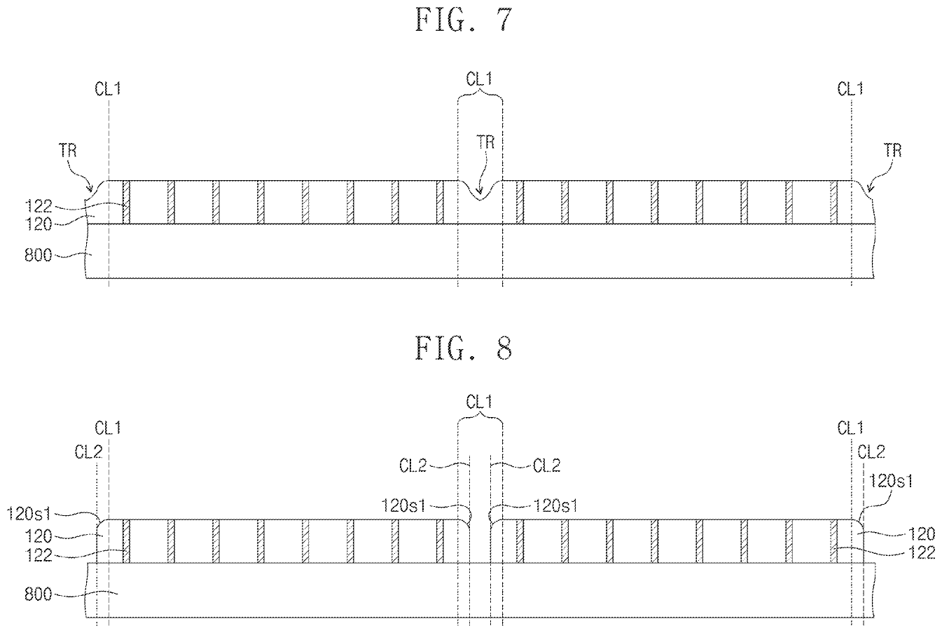

Referring to FIG. 9, the insulating element 124 may be formed on the top surface of the carrier 800 to enclose the core portions 120. For example, an epoxy resin film may be formed to cover the core portions 120 on the top surface of the carrier 800 and may be cured to form the insulating element 124. A portion of a top surface of the insulating element 124 may be removed.

For example, a grinding process or a chemical mechanical polishing (CMP) process may be performed on the top surface of the insulating element 124 to remove a portion of the insulating element 124. The grinding process or the CMP process may be performed to expose the top surfaces of the core portions 120 and the top surfaces of the core penetration vias 122.

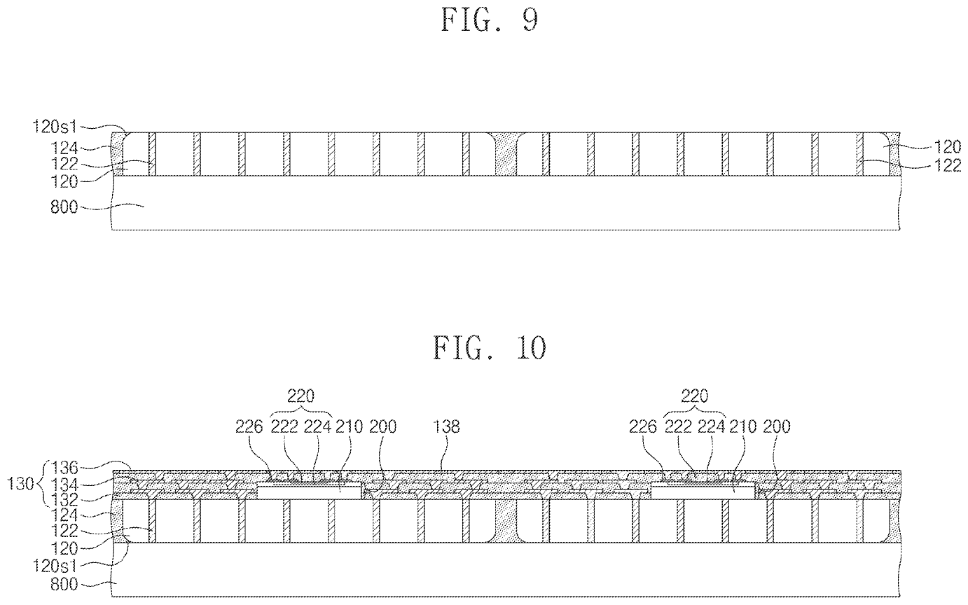

Referring to FIG. 10, the bridge chips 200 may be attached to the core portions 120, respectively. The bridge chip 200 may be formed to have substantially the same or similar features as the bridge chip 200 described with reference to FIG. 1. The description that follows will refer to a structure including one core portion 120 and one bridge chip 200. Although not shown, the bridge chip 200 may be attached to the core portion 120 using an adhesive layer. For example, the adhesive layer may be attached to the rear surface of the bridge chip 200, and the bridge chip 200 may be attached to the top surface of the core portion 120.

The second re-distribution layer 130 may be formed on the core portions 120. For example, an insulating layer may be formed on the top surfaces of the core portions 120 and may be patterned to form one second insulating pattern 132. A conductive layer may be formed on the second insulating pattern 132 and may be patterned to form one second interconnection pattern 134. The process of forming the second insulating pattern 132 and the second interconnection pattern 134 may be repeatedly performed. Here, the substrate protection layer 138 may form the insulating layer and the upper pads 136. The substrate protection layer 138 may be formed on the uppermost portion of the second re-distribution layer 130, and the upper pads 136 may be the second interconnection patterns 134, which may be formed to penetrate the substrate protection layer 138 and may be exposed to the outside of the second re-distribution layer 130 near the top surface of the second re-distribution layer 130. In an embodiment, the substrate protection layer 138 and the upper pads 136 may be separately formed on the top surface of the second re-distribution layer 130. In detail, the substrate protection layer 138 may be formed by forming a photoimageable insulating layer on the second insulating pattern 132. Penetration holes exposing the upper pads 136 may be formed by performing exposing and developing processes on the substrate protection layer 138. The upper pads 136 may be formed in the penetration holes. For example, the upper pads 136 may be formed by filling the penetration holes of the substrate protection layer 138 with a conductive material. The second insulating patterns 132, the second interconnection patterns 134, the substrate protection layer 138, and the upper pads 136, which may be formed by the afore-described method(s), may constitute the second re-distribution layer 130 previously described with reference to FIG. 1 and FIG. 2. The second re-distribution layer 130 may be formed to enclose the bridge chip 200. That is, the second re-distribution layer 130 may be formed to be in contact with a top surface and opposite side surfaces of the bridge chip 200.

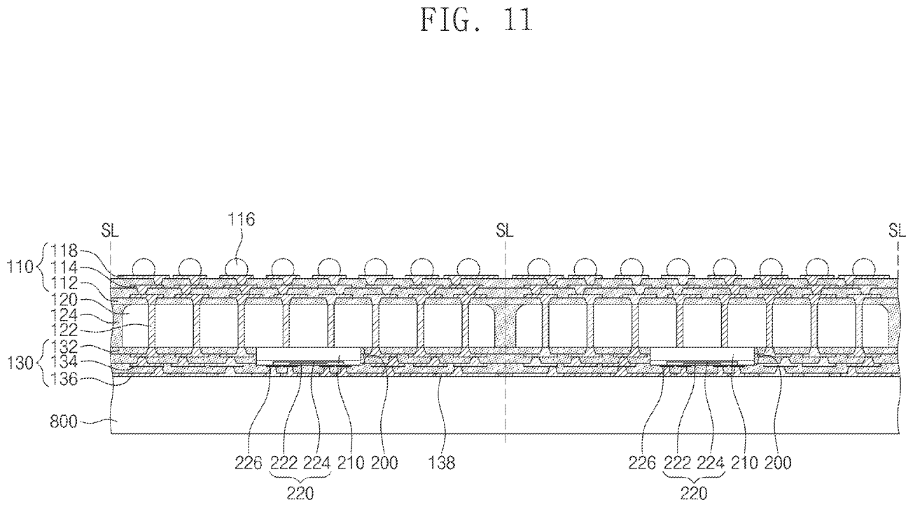

Referring to FIG. 11, the resulting structure of FIG. 10 may be inverted. Accordingly, the second re-distribution layer 130 may be placed below the core portion 120.

The first re-distribution layer 110 may be formed on the core portions 120. For example, an insulating layer may be formed on the top surfaces of the core portions 120 and may be patterned to form the first insulating pattern 112. A conductive layer may be formed on the first insulating pattern 112 and may be patterned to form one first interconnection pattern 114. The afore-described process of forming the first insulating pattern 112 and the first interconnection pattern 114 may be repeatedly performed. The lower pads 118 may be the first interconnection patterns 114, which may be exposed near the first insulating pattern 112 placed at the uppermost level of the first re-distribution layer 110. The first insulating patterns 112, the first interconnection patterns 114, and the lower pads 118 may constitute the first re-distribution layer 110 previously described with reference to FIG. 1 and FIG. 2.

The outer terminals 116 may be disposed on the first re-distribution layer 110. The outer terminals 116 may be provided on top surfaces of the lower pads 118, which may be exposed to the outside of the first re-distribution layer 110 near the top surface of the first re-distribution layer 110. For example, connection terminals, such as solder balls or solder bumps, may be attached to the top surfaces of the lower pads 118. After the formation of the outer terminals 116, a sawing process may be performed on the first re-distribution layer 110, the insulating element 124, and the second re-distribution layer 130. The sawing process may be performed along a sawing line SL. The sawing line SL may be substantially perpendicular to a top surface of the first re-distribution layer 110. As a result of the sawing process, a plurality of wiring substrates 100 may be separated from each other.

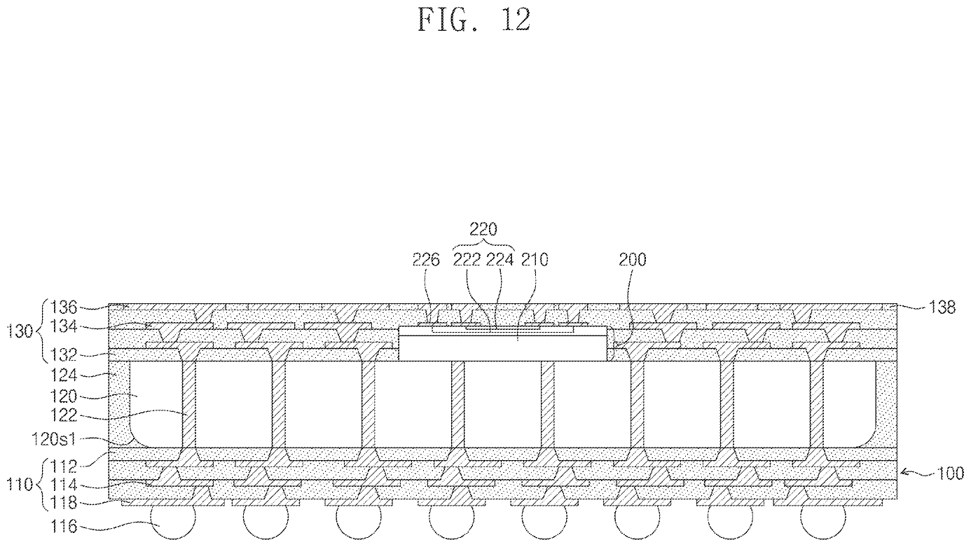

Referring to FIG. 12, the carrier 800 may be removed from the resulting structure of FIG. 11. The wiring substrate 100 may be formed by the afore-described method(s). This may be substantially the same or similar as the wiring substrate 100 previously described with reference to FIG. 1.

According to an embodiment of the inventive concept, the first intermediate surface 120s1 connecting the side surface of the core portion 120 to the bottom surface of the core portion 120 may be provided to have a shape capable of alleviating a vertical stress on the side surface of the core portion 120. In addition, the insulating element 124 may be formed to enclose the core portion 120, and it may be possible to protect the core portion 120 from an external force. Accordingly, it may be possible to provide a wiring substrate with improved mechanical durability and a semiconductor package including the same.

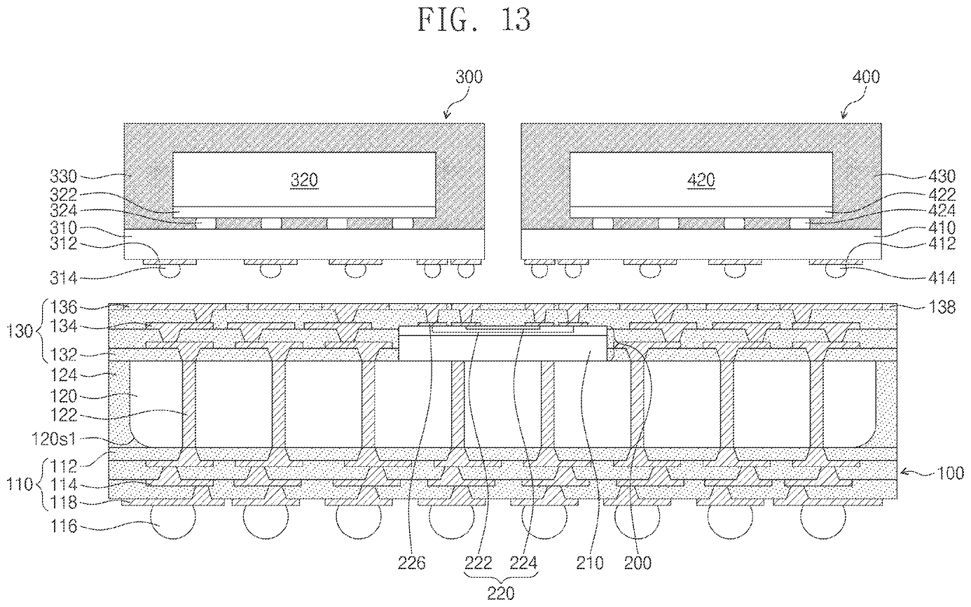

Referring to FIG. 13, the first device 300 and the second device 400 may be disposed on the wiring substrate 100. The first device 300 may be substantially the same or similar as the first device 300 described with reference to FIG. 1 and FIG. 2. For example, the first device 300 may include the first substrate 310, the first semiconductor chip 320, and the first mold layer 330. The first substrate 310 may include the first pads 312, which may be disposed on the bottom surface of the first substrate 310.

The first device 300 may be mounted on the wiring substrate 100. The first device 300 may be placed on the wiring substrate 100. For example, the first device 300 may be aligned to the wiring substrate 100 such that the first pads 312 may be placed on the upper pads 136 and the bridge pads 226 on the first region described with reference to FIG. 1. The first device 300 may be moved toward the wiring substrate 100 such that the first connection terminals 314 may be in contact with the upper pads 136 on the first region and the bridge pads 226 on the first region. A soldering process may be performed on the first connection terminals 314. Accordingly, the first connection terminals 314 may connect the first pads 312 to the upper pads 136 on the first region, and may connect the first pads 312 to the bridge pads 226 on the first region.

The second device 400 may be substantially the same or similar as the second device 400 described with reference to FIG. 1 and FIG. 2. For example, the second device 400 may include the second substrate 410, the second semiconductor chip 420, and the second mold layer 430. The second substrate 410 may include the second pads 412 disposed on the bottom surface of the second substrate 410.

The second device 400 may be mounted on the wiring substrate 100. The second device 400 may be placed on the wiring substrate 100. For example, the second device 400 may be aligned to the wiring substrate 100 such that the second pads 412 are placed on the upper and bridge pads 136 and 226 on the second region described with reference to FIG. 1. The second device 400 may be moved toward the wiring substrate 100 such that the second connection terminals 414 may be in contact with the upper and bridge pads 136 and 226 on the second region. A soldering process may be performed on the second connection terminals 414. Accordingly, the second connection terminals 414 may connect the second pads 412 to the upper pads 136 on the second region and may connect the second pads 412 to the bridge pads 226 on the second region.

The wiring substrate 100 and the semiconductor package therewith may be provided by the afore-described method(s).

According to an embodiment of the inventive concept, an intermediate surface may be provided to connect a bottom surface of a core portion to a side surface of the core portion. The intermediate surface, on which a load of a semiconductor package may be concentrated, may be provided to have a shape capable of alleviating a vertical stress on a side surface of the core portion.

Accordingly, the mechanical durability of the core portion may be improved.

In addition, an insulating element may be formed to enclose the core portion, and thus, it may be possible to protect the side surface of the core portion from an external force. Thus, a wiring substrate with improved mechanical durability and a semiconductor package including the same may be provided.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor package, comprising:
a wiring substrate;
a first chip on the wiring substrate; and
a second chip on the wiring substrate and horizontally spaced apart from the first chip,
wherein the wiring substrate comprises:
a core portion;
a first re-distribution layer on a bottom surface of the core portion;
a bridge chip on a top surface of the core portion;
a second re-distribution layer on the top surface of the core portion to cover the top surface of the core portion and the bridge chip; and
an insulating element between the first re-distribution layer and the second re-distribution layer and enclosing the core portion,
wherein the bottom surface of the core portion and a side surface of the core portion are spaced apart from each other in a direction perpendicular to a top surface of the first re-distribution layer.

2. The semiconductor package of claim 1, wherein the insulating element comprises an epoxy resin.

3. The semiconductor package of claim 1, wherein the core portion further comprises a first intermediate surface connecting the bottom surface of the core portion to the side surface of the core portion.

4. The semiconductor package of claim 3, wherein the first intermediate surface is a rounded surface.

5. The semiconductor package of claim 3, wherein the first intermediate surface is a flat surface.

6. The semiconductor package of claim 3, wherein the first intermediate surface comprises:
a first surface extending from the bottom surface of the core portion; and
a second surface extending from the side surface of the core portion toward the first surface,
wherein the first surface is inclined relative to both the bottom surface of the core portion and the second surface,
the second surface is inclined relative to both the side surface of the core portion and the first surface, and
a first angle between the bottom surface of the core portion and the first surface, a second angle between the first surface and the second surface, and a third angle between the second surface and the side surface of the core portion are obtuse angles.

7. The semiconductor package of claim 3, wherein the insulating element encloses the side surface of the core portion and the first intermediate surface.

8. The semiconductor package of claim 3, wherein an interface between the insulating element and the first re-distribution layer is located at a level higher than the bottom surface of the core portion.

9. The semiconductor package of claim 3, wherein the top surface of the core portion and the side surface of the core portion are spaced apart from each other in a direction perpendicular to a bottom surface of the second re-distribution layer, and
the core portion comprises a second intermediate surface connecting the top surface of the core portion to the side surface of the core portion.

10. The semiconductor package of claim 9, wherein the second intermediate surface is a rounded surface.

11. The semiconductor package of claim 9, wherein the insulating element comprises:
a first insulating element; and
a second insulating element on the first insulating element,
wherein the first insulating element encloses the side surface of the core portion and at least a portion of the first intermediate surface, and
the second insulating element encloses at least a portion of the second intermediate surface.

12. The semiconductor package of claim 11, wherein an interface between the second insulating element and the second re-distribution layer is located at a level lower than the top surface of the core portion.

13. The semiconductor package of claim 11, wherein an interface between the first insulating element and the second insulating element is in contact with the second intermediate surface.

14. A wiring substrate, comprising:
a first re-distribution layer;
a second re-distribution layer on the first re-distribution layer; and
a core portion between the first re-distribution layer and the second re-distribution layer,
wherein the core portion comprises:
a bottom surface disposed on a top surface of the first re-distribution layer; and
a first intermediate surface disposed on the top surface of the first re-distribution layer,
wherein a distance between the top surface of the first re-distribution layer and the core portion along the first intermediate surface, which is measured in a direction perpendicular to the top surface of the first re-distribution layer, increases as a distance from the bottom surface increases.

15. The wiring substrate of claim 14, wherein the first intermediate surface extends from the bottom surface, and
the first intermediate surface connects a side surface of the core portion to the bottom surface of the core portion.

16. The wiring substrate of claim 15, wherein the first intermediate surface of the core portion is a rounded surface.

17. The wiring substrate of claim 15, further comprising an insulating element between the first re-distribution layer and the second re-distribution layer and enclosing the side surface and the bottom surface of the core portion.

18. The wiring substrate of claim 17, wherein the insulating element comprises an insulating film.

19. A wiring substrate, comprising:
a core portion;
a lower re-distribution layer on a bottom surface of the core portion;
an upper re-distribution layer on a top surface of the core portion; and
an insulating element between the lower re-distribution layer and the upper re-distribution layer enclosing the core portion,
wherein the core portion comprises:
an upper portion in contact with a bottom surface of the upper re-distribution layer; and
a lower portion in contact with a top surface of the lower re-distribution layer,
wherein a width of the upper portion of the core portion is uniform,
a width of the lower portion of the core portion decreases as a distance to the top surface of the lower re-distribution layer decreases, and
at an interface between the upper portion and the lower portion, the width of the upper portion is substantially equal to the width of the lower portion.

20. The wiring substrate of claim 19, wherein the insulating element comprises:
an upper insulating element enclosing the upper portion of the core portion; and
a lower insulating element enclosing the lower portion of the core portion,
wherein a width of the upper insulating element is uniform, and
a width of the lower insulating element increases as a distance to the top surface of the lower re-distribution layer decreases.
